(19) United States
(12) Patent Application Publication
(10) Pub. No.: US 2018/0315519 A1
(43) Pub. Date: Nov. 1, 2018

(54) COATING LIQUID FOR FORMING CONDUCTIVE LAYER AND METHOD FOR MANUFACTURING CONDUCTIVE LAYER

(71) Applicants: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(72) Inventors: Motohiko SUGIURA, Osaka-shi, Osaka (JP); Issei OKADA, Osaka-shi, Osaka (JP); Yoshio OKA, Osaka-shi, Osaka (JP); Kenji OHKI, Koka-shi, Shiga (JP)

(73) Assignees: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(21) Appl. No.: 15/756,629

(22) PCT Filed: Sep. 27, 2016
(86) PCT No.: PCT/JP2016/078328

§ 371 Date: Mar. 1, 2018

(30) Foreign Application Priority Data
Sep. 30, 2015 (JP) 2015-193141

(51) Int. Cl. H01B 1/22; H05K 3/38; H01B 1/12; H05K 3/46

(52) U.S. Cl. CPC H01B 1/22; H05K 3/381; H01B 13/00; H05K 3/4664; H01B 1/124

(57) ABSTRACT

A coating liquid for forming a conductive layer according to an embodiment of the present invention contains fine metal particles, a dispersion medium, and a dispersant. The coating liquid has a pH of 4 or more and 8 or less, an electrical conductivity of 100 μS/cm or more and 800 μS/cm or less, and a content of the fine metal particles of 20% by mass or more and 80% by mass or less. A method for manufacturing a conductive layer according to another embodiment of the present invention is a method for manufacturing a conductive layer using a coating liquid for forming a conductive layer, the coating liquid containing fine metal particles, a dispersion medium, and a dispersant. The method includes an application step of applying the coating liquid for forming a conductive layer, and a heating step of heating the coating liquid for forming a conductive layer after application. At the time of the application, the coating liquid for forming a conductive layer has a pH of 4 or more and 8 or less, an electrical conductivity of 100 μS/cm or more and 800 μS/cm or less, and a content of the fine metal particles of 20% by mass or more and 80% by mass or less.

### TECHNICAL FIELD

The present invention relates to a coating liquid for forming a conductive layer and a method for manufacturing a conductive layer.

The present application claims priority from Japanese Patent Application No. 2015-filed on Sep. 30, 2015, and the entire contents of the Japanese application are incorporated herein by reference.

### BACKGROUND ART

In recent years, with the realization of electronic devices having a smaller size and higher performance, there has been a need for a higher density of printed circuit boards.

To meet this requirement, a printed circuit board base material has been proposed in which a thin copper layer is formed on a heat-resistant insulting base film without providing an adhesive layer therebetween (refer to Japanese Unexamined Patent Application Publication No. 9-136378). The printed circuit board base material described in this patent application publication is obtained by forming a thin copper layer having a thickness of 0.25 to 0.30 μm on a surface of a heat-resistant insulating base film by sputtering. According to this printed circuit board base material, a high density can be realized by forming a thick copper layer on an outer surface of the thin copper layer by electroplating, while adhesive strength between the base film and the thin copper layer is sufficiently ensured.

### CITATION LIST

### Patent Literature

PTL 1: Japanese Unexamined Patent Application Publication No. 9-136378

### SUMMARY OF INVENTION

A coating liquid for forming a conductive layer according to an embodiment of the present invention is a coating liquid for forming a conductive layer, the coating liquid containing fine metal particles, a dispersion medium, and a dispersant. The coating liquid has a pH of 4 or more and 8 or less, an electrical conductivity of 100 μS/cm or more and 800 μS/cm or less, and a content of the fine metal particles of 20% by mass or more and 80% by mass or less.

A method for manufacturing a conductive layer according to another embodiment of the present invention is a method for manufacturing a conducting layer using a coating liquid for forming a conductive layer, the coating liquid containing fine metal particles, a dispersion medium, and a dispersant. The method includes an application step of applying the coating liquid for forming a conductive layer, and a heating step of heating the coating liquid for forming a conductive layer after application. At the time of the application, the coating liquid for forming a conductive layer has a pH of 4 or more and 8 or less, an electrical conductivity of 100 μS/cm or more and 800 μS/cm or less, and a content of the fine metal particles of 20% by mass or more and 80% by mass or less.

### BRIEF DESCRIPTION OF DRAWINGS

FIG. 1 is a schematic sectional view illustrating an application step of a method for manufacturing a conductive layer according to an embodiment of the present invention.

FIG. 2 is a schematic sectional view illustrating a heating step of a method for manufacturing a conductive layer according to an embodiment of the present invention.

FIG. 3 is a schematic sectional view illustrating a first-metal plating layer formation step of a method for manufacturing a conductive layer according to an embodiment of the present invention.

FIG. 4 is a schematic sectional view illustrating a second-metal plating layer formation step of a method for manufacturing a conductive layer according to an embodiment of the present invention.

### DESCRIPTION OF EMBODIMENTS

### Technical Problem

The printed circuit board base material described in the above patent application publication satisfies the requirement for high-density printed circuits in that a thin copper layer can be formed directly on a base film. However, since the thin copper layer is formed by sputtering, the printed circuit board base material is disadvantageous in that vacuum equipment is necessary, resulting in an increase in the equipment costs, for example, the costs of installation, maintenance, and operation of the equipment. Furthermore, this printed circuit board base material needs to be formed under vacuum conditions using vacuum equipment, and thus an increase in the size of the base material is limited.

The present invention has been made in view of the circumstances described above. An object of the present invention is to provide a coating liquid for forming a conductive layer, the coating liquid being capable of easily and reliably forming a conductive layer having a certain thickness at a relatively low cost, and a method for manufacturing a conductive layer using the coating liquid for forming a conductive layer.

### Advantageous Effects of the Present Disclosure

According to the coating liquid for forming a conductive layer and the method for manufacturing a conductive layer of the present invention, a conductive layer having a certain thickness can be easily and reliably formed at a relatively low cost.

### Description of Embodiments of the Present Invention

First, embodiments of the present invention will be listed and described.

A coating liquid for forming a conductive layer according to an embodiment of the present invention is a coating liquid for forming a conductive layer, the coating liquid containing fine metal particles, a dispersion medium, and a dispersant. The coating liquid has a pH of 4 or more and 8 or less, an electrical conductivity of 100 μS/cm or more and 800 μS/cm or less, and a content of the fine metal particles of 20% by mass or more and 80% by mass or less.

The coating liquid for forming a conductive layer contains a dispersion medium and a dispersant, and the pH and the electrical conductivity of the coating liquid are adjusted to the above ranges. Therefore, even though the content of the fine metal particles is high, that is, within the above range, the fine metal particles have good uniform dispersibility in the dispersion medium. Accordingly, for example, by applying the coating liquid for forming a conductive layer to a surface of a base film that forms a printed circuit board base material and heating the coating liquid, a conductive layer which has a certain thickness and in which fine metal particles are arranged at a high density can be easily and reliably formed. In addition, the coating liquid for forming a conductive layer can provide a conductive layer at a relatively low cost without using expensive vacuum equipment, which is necessary for physical vapor deposition such as sputtering. Furthermore, according to the coating liquid for forming a conductive layer, it is not necessary to use vacuum equipment when the conductive layer is formed, and thus it is possible to prevent the dimensions of the conductive layer from being limited by the size of the vacuum equipment. As a result, a conductive layer having large outer dimensions is easily formed by using the coating liquid for forming a conductive layer.

The dispersant is preferably a polymer compound. When the dispersant is a polymer dispersant, the fine metal particles are easily uniformly dispersed in the dispersion medium while aggregation of the fine metal particles is prevented. Accordingly, a conductive layer that is dense and free of cracks is easily formed.

The polymer compound preferably has an imino group. When the polymer compound has an imino group, the fine metal particles are easily dispersed in the dispersion medium more uniformly while aggregation of the fine metal particles is easily and reliably prevented.

The polymer compound is preferably polyethyleneimine or a polyethyleneimine-ethylene oxide adduct. When the polymer compound is polyethyleneimine or a polyethyleneimine-ethylene oxide adduct, the fine metal particles are easily dispersed in the dispersion medium still more uniformly while aggregation of the fine metal particles is easily and reliably prevented.

The fine metal particles preferably have an average particle size D₅₀ of 1 nm or more and 500 nm or less, the average particle size D₅₀ being calculated from a cumulative distribution measured by a laser diffraction method. According to the coating liquid for forming a conductive layer, even when the fine metal particles have a relatively small average particle size D₅₀ within the above range, the fine metal particles can be uniformly dispersed in the dispersion medium. Thus, an average particle size D₅₀ of the fine metal particles within the above range enables a dense conductive layer to be formed easily and reliably. The term “average particle size D₅₀” refers to a value calculated from a cumulative volume distribution.

The coating liquid for forming a conductive layer preferably has a viscosity of 100 mPa·s or less at 25° C. When the viscosity at 25° C. is equal to or less than the upper limit, coating properties of the coating liquid for forming a conductive layer can be improved.

The fine metal particles preferably contain copper or a copper alloy as a main component. The fine metal particles containing copper or a copper alloy as a main component enable a conductive layer having a good electrical conductivity to be formed.

A method for manufacturing a conductive layer according to another embodiment of the present invention is a method for manufacturing a conducting layer using a coating liquid for forming a conductive layer, the coating liquid containing fine metal particles, a dispersion medium, and a dispersant. The method includes an application step of applying the coating liquid for forming a conductive layer, and a heating step of heating the coating liquid for forming a conductive layer after application. At the time of the application, the coating liquid for forming a conductive layer has a pH of 4 or more and 8 or less, an electrical conductivity of 100 μS/cm or more and 800 μS/cm or less, and a content of the fine metal particles of 20% by mass or more and 80% by mass or less.

According to the method for manufacturing a conductive layer, the coating liquid for forming a conductive layer contains a dispersion medium and a dispersant, and, at the time of the application, the coating liquid for forming a conductive layer has a pH and an electrical conductivity within the above ranges. Therefore, even when the content of the fine metal particles is high, that is, within the above range, the fine metal particles have good uniform dispersibility at the time of the application. Thus, according to the method for manufacturing a conductive layer, a conductive layer which has a certain thickness and in which fine metal particles are arranged at a high density can be easily and reliably formed. According to the method for manufacturing a conductive layer, a conductive layer can be formed at a relatively low cost without using expensive vacuum equipment, which is necessary for physical vapor deposition such as sputtering. Furtheimore, since the method for manufacturing a conductive layer does not require use of vacuum equipment, it is possible to prevent the dimensions of the conductive layer from being limited by the size of the vacuum equipment. As a result, a conductive layer having large outer dimensions is easily formed by the method for manufacturing a conductive layer.

Herein, the term “electrical conductivity” refers to a value measured in accordance with JIS-K0130: 2008. The term “viscosity” refers to a value measured in accordance with JIS-Z8803: 2011. The term “main component” refers to a component having the highest content and refers to a component contained in an amount of, for example, 50% by mass or more and preferably 80% by mass or more.

### Details of Embodiments of the Present Invention

<Coating Liquid for Forming Conductive Layer>

The coating liquid for forming a conductive layer is used for, for example, forming a printed circuit board base material. Specifically, the coating liquid for forming a conductive layer is applied to a surface of a base film that forms a printed circuit board, dried, and subjected to heat treatment, thus forming a conductive layer (fine metal particle-sintered layer) which is disposed on the surface of the base film and formed of sintered fine metal particles.

The coating liquid for forming a conductive layer contains fine metal particles, a dispersion medium, and a dispersant. The coating liquid for forming a conductive layer has a pH of 4 or more and 8 or less, an electrical conductivity of 100 μS/cm or more and 800 μS/cm or less, and a content of the fine metal particles of 20% by mass or more and 80% by mass or less. Since the coating liquid for forming a conductive layer contains a dispersion medium and a dispersant, and the pH and the electrical conductivity of the coating liquid are within the above ranges, the fine metal particles have good uniform dispersibility in the dispersion medium even though the content of the fine metal particles is high, that is, within the above range. Therefore, for example, by applying the coating liquid for forming a conductive layer to a surface of a base film and heating the coating liquid, a conductive layer which has a certain thickness and in which fine metal particles are arranged at a high density can be easily and reliably formed. In addition, the coating liquid for forming a conductive layer can provide a conductive layer at a relatively low cost without using expensive vacuum equipment, which is necessary for physical vapor deposition such as sputtering. Furthermore, according to the coating liquid for forming a conductive layer, it is not necessary to use vacuum equipment when a conductive layer is formed, and thus it is possible to prevent the dimensions of the conductive layer from being limited by the size of the vacuum equipment. As a result, a conductive layer having large outer dimensions is easily formed by using the coating liquid for forming a conductive layer.

Water is typically used as the dispersion medium contained in the coating liquid for forming a conductive layer, but the dispersion medium is not particularly limited thereto.

Examples of the main component of the fine metal particles contained in the coating liquid for forming a conductive layer include copper (Cu), nickel (Ni), aluminum (Al), gold (Au), silver (Ag), and alloys thereof. Of these, copper or a copper alloy, which has a good electrical conductivity and easily enhances the adhesive strength to the base film, is preferred.

The lower limit of the content of the fine metal particles in the coating liquid for forming a conductive layer is preferably 20% by mass and more preferably 25% by mass. The upper limit of the fine metal particles is 80% by mass, more preferably 50% by mass, and still more preferably 35% by mass. When the content of the fine metal particles is less than the lower limit, it may become difficult to form a conductive layer having a sufficient thickness and a sufficient density. In contrast, when the content of the fine metal particles exceeds the upper limit, it may become difficult to uniformly disperse the fine metal particles in the dispersion medium.

The lower limit of the average particle size D₅₀ of the fine metal particles, the average particle size D₅₀ being calculated from a cumulative volume distribution measured by a laser diffraction method, is preferably 1 nm and more preferably 30 nm. The upper limit of the average particle size D₅₀ is preferably 500 nm, more preferably 200 nm, and still more preferably 100 nm. When the average particle size D₅₀ is less than the lower limit, dispersibility and stability of the fine metal particles in the dispersion medium may decrease. In contrast, when the average particle size D₅₀ exceeds the upper limit, in application of the coating liquid for forming a conductive layer, the density of the fine metal particles may become nonuniform. As a result, it may become difficult to form a sufficiently dense conductive layer.

The lower limit of an average particle size D_{50 SEM} of the fine metal particles, the average particle size D_{50 SEM} being calculated on the basis of a measurement by scanning electron microscopy (SEM), is preferably 1 nm and more preferably 30 nm. The upper limit of the average particle size D_{50 SEM} is preferably 550 nm, more preferably 250 nm, and still more preferably 150 nm. When the average particle size D_{50 SEM} is less than the lower limit, dispersibility and stability of the fine metal particles in the dispersion medium may decrease. In contrast, when the average particle size D_{50 SEM} exceeds the upper limit, in application of the coating liquid for forming a conductive layer, the density of the fine metal particles may become nonuniform. As a result, it may become difficult to form a sufficiently dense conductive layer. The term “average particle size D_{50 SEM}” refers to a particle size at which a cumulative volume is 50% when surfaces of fine metal particles are observed with a scanning electron microscope (SEM) to measure the sizes of 100 fine metal particles that are arbitrarily selected, and the volume is accumulated in the ascending order of the particle size.

The upper limit of a ratio (D_{50 SEM}/D₅₀) of the average particle size D_{50 SEM} of the fine metal particles calculated on the basis of the measurement with a scanning electron microscope to the average particle size D₅₀ of the fine metal particles calculated from the cumulative distribution measured by the laser diffraction method is preferably 1.5 and more preferably 1.3. When the ratio (D_{50 SEM}/D₅₀) exceeds the upper limit, the fine metal particles tend to have nonuniform shapes. As a result, the surface of a coating film formed by applying the coating liquid for forming a conductive layer has insufficient smoothness. By extension, it may become difficult to form a sufficiently dense conductive layer. The lower limit of the ratio (D_{50 SEM}/D₅₀) is not particularly limited and may be, for example, 1.

The dispersant is not particularly limited as long as fine metal particles can be satisfactorily dispersed in the dispersion medium. Polymer compounds are preferably used. When the dispersant of the coating liquid for forming a conductive layer is a polymer dispersant, the fine metal particles are easily uniformly dispersed in the dispersion medium while aggregation of the fine metal particles is prevented. Therefore, when the dispersant is a polymer dispersant, a conductive layer that is dense and free of cracks is easily formed by using the coating liquid for forming a conductive layer.

The polymer compounds are preferably polymer compounds that do not contain sulfur, phosphorus, boron, a halogen atom, and an alkali metal from the viewpoint of preventing deterioration of components. Examples thereof include polyalkyleneimines such as polyethyleneimine, polypropyleneimine, and polyhexamethyleneimine; amine polymer compounds such as polyvinylpyrrolidone; hydrocarbon polymer compounds having a carboxylic acid group in the molecule thereof, such as polyacrylic acid and carboxymethyl cellulose; Poval (polyvinyl alcohol); styrene-maleic acid copolymers; olefin-maleic acid copolymers; and polyethyleneimine-ethylene oxide adducts having a polyethyleneimine moiety and a polyethylene oxide moiety in one molecule thereof. Of these, compounds having an imino group are preferred, and polyethyleneimine and polyethyleneimine-ethylene oxide adducts are particularly preferred as the polymer compounds. According to the coating liquid for forming a conductive layer, when the polymer compound has an imino group, fine metal particles can be more uniformly dispersed in the dispersion medium while aggregation of the fine metal particles is easily and reliably prevented. In particular, according to the coating liquid for forming a conductive layer, when the polymer compound is polyethyleneimine or a polyethyleneimine-ethylene oxide adduct, the content of nitrogen atoms of the polymer compound can be increased, and thus fine metal particles can be still more uniformly dispersed in the dispersion medium while aggregation of the fine metal particles is more easily and reliably prevented.

The lower limit of the weight-average molecular weight of the polymer compound is preferably 2,000 and more preferably 5,000. The upper limit of the weight-average molecular weight of the polymer compound is preferably 750,000 and more preferably 100,000. When the weight-average molecular weight of the polymer compound is less than the lower limit, the effect of preventing aggregation of the fine metal particles and maintaining dispersion of the fine metal particles may be insufficiently provided. As a result, it may become difficult to form a conductive layer that is dense and free of cracks. In contrast, when the weight-average molecular weight of the polymer compound exceeds the upper limit, the dispersant is excessively bulky. Thus, in heat treatment performed after application of the coating liquid for forming a conductive layer, the dispersant may inhibit sintering of the fine metal particles, which may result in formation of voids. Furthermore, when the dispersant is excessively bulky, the denseness of the conductive layer may decrease, or the electrical conductivity of the conductive layer may decrease due to decomposition residues of the dispersant.

The lower limit of the content of the dispersant in the coating liquid for forming a conductive layer is preferably 0.01% by mass and more preferably 0.02% by mass. The upper limit of the content of the dispersant is preferably 2% by mass and more preferably 1% by mass. When the content of the dispersant is less than the lower limit, the fine metal particles cannot be sufficiently surrounded by the dispersant, and aggregation of the fine metal particles may not be sufficiently prevented. In contrast, when the content of the dispersant exceeds the upper limit, in heat treatment performed after application of the coating liquid for forming a conductive layer, the excessive dispersant may inhibit firing including sintering of the fine metal particles, which may result in formation of voids. In addition, decomposition residues of the dispersant remain as impurities in the resulting conductive layer, and the electrical conductivity of the conductive layer may decrease.

The coating liquid for forming a conductive layer may optionally contain an organic solvent. Various water-soluble organic solvents can be used as the organic solvent. Examples thereof include alcohols such as methyl alcohol, ethyl alcohol, n-propyl alcohol, isopropyl alcohol, n-butyl alcohol, isobutyl alcohol, sec-butyl alcohol, and tert-butyl alcohol; ketones such as acetone and methyl ethyl ketone; esters of a polyhydric alcohol such as ethylene glycol or glycerin or another compound; and glycol ethers such as ethylene glycol monoethyl ether and diethylene glycol monobutyl ether.

When the coating liquid for forming a conductive layer contains an organic solvent, the lower limit of the content of the organic solvent in the coating liquid for forming a conductive layer is preferably 25% by mass and more preferably 30% by mass. The upper limit of the content of the organic solvent is preferably 75% by mass and more preferably 70% by mass. When the content of the organic solvent is less than the lower limit, the effect of, for example, adjusting the viscosity and adjusting the vapor pressure, the effect being exerted by the organic solvent, may be insufficiently provided. In contrast, when the content of the organic solvent exceeds the upper limit, the effect of swelling the dispersant exerted by water may be insufficiently provided, which may result in aggregation of the fine metal particles in the coating liquid for forming a conductive layer.

The pH of the coating liquid for forming a conductive layer is adjusted to 4 or more and 8 or less as described above. When the dispersant is polyethyleneimine, the lower limit of the pH of the coating liquid for forming a conductive layer is preferably 6 and more preferably 6.5. When the dispersant is polyethyleneimine, the upper limit of the pH of the coating liquid for forming a conductive layer is preferably 7.5. When the dispersant is a polyethyleneimine-ethylene oxide adduct, the lower limit of the pH of the coating liquid for forming a conductive layer is preferably 4.5 and more preferably 5. When the dispersant is a polyethyleneimine-ethylene oxide adduct, the upper limit of the pH of the coating liquid for forming a conductive layer is preferably 7 and more preferably 6.0. When the pH is less than the lower limit, the fine metal particles may be easily dissolved. In contrast, when the pH exceeds the upper limit, uniform dispersibility of the fine metal particles may be degraded by the action of hydroxide ions.

The lower limit of the electrical conductivity of the coating liquid for forming a conductive layer is 100 μS/cm, preferably 150 μS/cm, and more preferably 200 μS/cm. The upper limit of the electrical conductivity is 800 μS/cm, preferably 700 μS/cm, and more preferably 600 μS/cm. When the electrical conductivity is less than the lower limit, the fine metal particles may be easily aggregated. In contrast, when the electrical conductivity exceeds the upper limit, decomposition residues of the dispersant etc. easily remain as impurities in a conductive layer formed from the coating liquid for forming a conductive layer. As a result, the electrical conductivity of the conductive layer may decrease.

The upper limit of the viscosity at 25° C. of the coating liquid for forming a conductive layer is preferably 100 mPa·s, more preferably 30 mPa·s, and still more preferably 2 mPa·s. The lower limit of the viscosity is preferably 1 mPa·s. When the viscosity exceeds the upper limit, coating properties may decrease. In contrast, when the viscosity is less than the lower limit, formability of a coating film may decrease.

<Method for Manufacturing the Coating Liquid for Forming a Conductive Layer>

A method for manufacturing the coating liquid for forming a conductive layer includes a fine metal particle manufacturing step of manufacturing fine metal particles, a washing step of washing the fine metal particles manufactured in the fine metal particle manufacturing step, and a dispersion step of dispersing the fine metal particles washed in the washing step.

(Fine Metal Particle Manufacturing Step)

The fine metal particle manufacturing step can be performed by a high-temperature treatment method, a liquid-phase reduction method, a gas-phase method, or the like. A method based on the liquid-phase reduction method will be described below as a preferred embodiment of the fine metal particle manufacturing step.

In order to manufacture the fine metal particles by the liquid-phase reduction method, for example, the dispersant and a water-soluble metal compound serving as a source of metal ions that are to form the metal particles are dissolved in water, and a reducing agent and a complexing agent serving as an optional component are added to cause a reduction reaction of the metal ions for a certain period of time. In the case of the liquid-phase reduction method, fine metal particles manufactured have a uniform spherical or granular shape and have a very small size. Examples of the water-soluble metal compound serving as the source of metal ions include, in the case of copper, copper(II) nitrate (Cu(NO₃)₂) and copper(II) sulfate pentahydrate (CuSO₄.5H₂O); in the case of silver, silver(I) nitrate (AgNO₃) and silver methanesulfonate (CH₃SO₃Ag); in the case of gold, tetrachloroauric(III) acid tetrahydrate (HAuCl₄.4H₂O); and, in the case of nickel, nickel(II) chloride hexahydrate (NiCl₂.6H₂O) and nickel(II) nitrate hexahydrate (Ni(NO₃)₂.6H₂O). Also for other fine metal particles, water-soluble compounds such as chlorides, nitrate compounds, and sulfate compounds can be used.

As the reducing agent, various reducing agents capable of reducing and precipitating metal ions in a reaction system of a liquid phase (aqueous solution) can be used. Examples of the reducing agent include sodium borohydride, sodium hypophosphite, hydrazine, transition metal ions such as a trivalent titanium ion and a divalent cobalt ion, ascorbic acid, reducing sugars such as glucose and fructose, and polyhydric alcohols such as ethylene glycol and glycerin. Of these, trivalent titanium ions are used to perform a titanium redox process in which metal ions are reduced by a redox action during oxidation of the trivalent titanium ions into tetravalent ions to precipitate fine metal particles. Fine metal particles obtained by the titanium redox process have a small and uniform particle size. In addition, the titanium redox process can provide fine metal particles having a spherical or granular shape. Therefore, use of the titanium redox process can promote densification of a conductive layer formed from the coating liquid for forming a conductive layer.

Examples of the complexing agent include sodium citrate, sodium gluconate, sodium acetate, sodium propionate, malic acid, lactic acid, Rochelle salt, sodium thiosulfate, sodium tartrate, ethylenediaminetetraacetic acid, and ammonia.

The particle size of the fine metal particles can be adjusted by adjusting the types and mixing ratio of the metal compound, the dispersant, the reducing agent, and the complexing agent, and by adjusting, for example, the stirring rate, the temperature, the time, and the pH during the reduction reaction of the metal compound. For example, the pH of the reaction system is preferably adjusted to 7 or more and 13 or less in order to obtain fine metal particles having a very small particle size as in this embodiment. At this time, a pH adjuster may be used so as to adjust the pH of the reaction system to be in the above range. A common acid or alkali such as hydrochloric acid, sulfuric acid, sodium hydroxide, or sodium carbonate may be used as the pH adjuster. In particular, in order to prevent peripheral components from deteriorating, nitric acid and ammonia, which are free from impurity elements such as alkali metals, alkaline-earth metals, halogen elements, e.g., chlorine, sulfur, phosphorus, and boron, may be used.

(Washing Step)

In the washing step, the fine metal particles precipitated in the fine metal particle manufacturing step are washed with water. Specifically, in the washing step, the fine metal particles and a liquid are separated by centrifugation, water is added to the fine metal particles after separation, and stirring is performed to wash the fine metal particles. The number of times of washing with water is not particularly limited but may be, for example, 1 or more and 3 or less and more preferably 2. In the method for manufacturing the coating liquid for forming a conductive layer, an increase in the number of times of washing with water can decrease the pH and electrical conductivity of the coating liquid for forming a conductive layer and the content of the dispersant in the coating liquid. With regard to this respect, by adjusting the number of times of washing with water to the above range, the pH and electrical conductivity of the coating liquid for forming a conductive layer and the content of the dispersant in the coating liquid can be easily adjusted to the ranges described above.

After the washing step in the method for manufacturing the coating liquid for forming a conductive layer, the fine metal particles are dried to form a powder, and the resulting powdery fine metal particles are preferably used in the dispersion step described below.

(Dispersion Step)

In the dispersion step, the fine metal particles after the washing step are dispersed in a dispersion medium. The dispersion step can be performed by, for example, incorporating, in water serving as the dispersion medium, the powdery fine metal particles obtained by drying after the washing step. Since the fine metal particles after the washing step are present in a state in which the particles are surrounded by the dispersant, the dispersant is not necessarily added to the dispersion medium in the dispersion step. However, the dispersant may be added to the dispersion medium according to need.

According to the method for manufacturing a coating liquid for forming a conductive layer, a coating liquid for forming a conductive layer, the coating liquid being capable of forming a conductive layer easily and reliably at a relatively low cost, can be easily and reliably manufactured.

<Method for Manufacturing Conductive Layer>

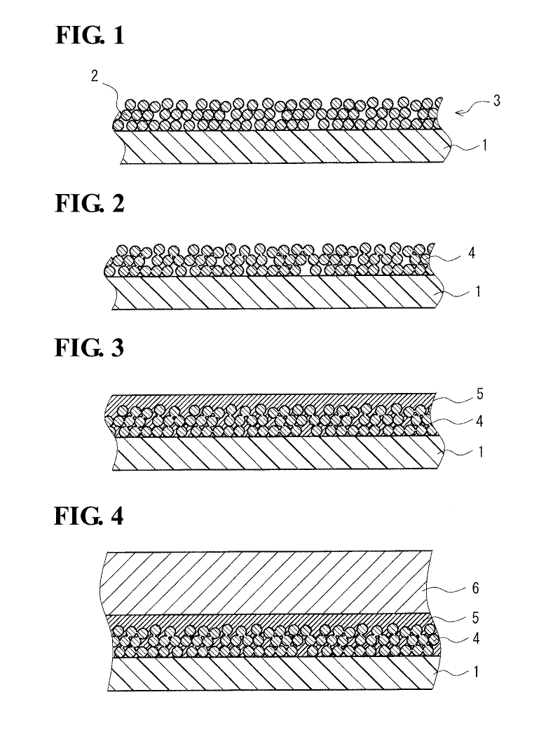

Next, a method for manufacturing a conductive layer using the coating liquid for forming a conductive layer will be described with reference to FIGS. 1 to 4. Hereinafter, a description will be given of a case where a conductive layer of a printed circuit board base material is manufactured by using the coating liquid for forming a conductive layer.

The method for manufacturing a conductive layer includes an application step of applying the coating liquid for forming a conductive layer and a heating step of heating the coating liquid for forming a conductive layer after application. The method for manufacturing a conductive layer may further include a metal plating layer formation step of forming a metal plating layer on an outer surface of a fine metal particle-sintered layer that is formed by sintering of fine metal particles due to the heating. According to the method for manufacturing a conductive layer, at the time of the application, the coating liquid for forming a conductive layer has a pH of 4 or more and 8 or less, an electrical conductivity of 100 μS/cm or more and 800 μS/cm or less, and a content of the fine metal particles of 20% by mass or more and 80% by mass or less. In the method for manufacturing a conductive layer of this embodiment, a laminated body including the fine metal particle-sintered layer and the metal plating layer is formed as a conductive layer.

According to the method for manufacturing a conductive layer, the coating liquid for forming a conductive layer contains a dispersion medium and a dispersant, and, at the time of the application, the coating liquid for forming a conductive layer has a pH and an electrical conductivity within the above ranges. Thus, the fine metal particles have good uniform dispersibility at the time of the application even though the content of the fine metal particles is high, that is, within the above range. Therefore, according to the method for manufacturing a conductive layer, a conductive layer which has a certain thickness and in which the fine metal particles are arranged at a high density can be formed easily and reliably. According to the method for manufacturing a conductive layer, a conductive layer can be formed at a relatively low cost without using expensive vacuum equipment, which is necessary for physical vapor deposition such as sputtering. Furthermore, since the method for manufacturing a conductive layer does not require use of vacuum equipment, it is possible to prevent the dimensions of the conductive layer from being limited by the size of the vacuum equipment. As a result, a conductive layer having large outer dimensions is easily formed by the method for manufacturing a conductive layer.

(Application Step)

In the application step, the coating liquid for forming a conductive layer is applied to one of surfaces of a base film 1, as illustrated in FIG. 1.

Examples of the main component of the base film 1 include flexible resins such as polyimides, liquid-crystal polymers, fluororesins, polyethylene terephthalate, and polyethylene naphthalate; rigid materials such as paper impregnated with a phenolic resin, paper impregnated with an epoxy resin, glass composites, fiberglass cloths impregnated with an epoxy resin, Teflon (registered trademark), and glass base materials; and rigid-flexible materials which are composites of a hard material and a soft material. Of these, polyimides are preferred because they exhibit high bonding strength to, for example, a metal oxide.

In the base film 1, the surface to which the coating liquid for forming a conductive layer is to be applied is preferably subjected to a hydrophilic treatment. Examples of the hydrophilic treatment include a plasma treatment for making an application surface hydrophilic by irradiation with plasma and an alkali treatment for making an application surface hydrophilic with an alkali solution. When the application surface is subjected to such a hydrophilic treatment, the coating liquid for forming a conductive layer exhibits a reduced surface tension to the application surface, and thus the coating liquid for forming a conductive layer can be uniformly applied to the application surface. Of these, a plasma treatment is preferred as the hydrophilic treatment.

Examples of the method for applying the coating liquid for forming a conductive layer to one of the surfaces of the base film 1 include conventionally known coating methods such as spin coating, spray coating, bar coating, die coating, slit coating, roll coating, and dip coating. Alternatively, the coating liquid for forming a conductive layer may be applied to only a portion of one of the surfaces of the base film 1 by, for example, a screen-printing method or using a dispenser. After the application of the coating liquid for forming a conductive layer, drying is performed at a temperature of, for example, room temperature or higher to form a coating film 3 containing fine metal particles 2. The upper limit of the drying temperature is preferably 100° C. and more preferably 40° C. When the drying temperature exceeds the upper limit, cracks may be formed in the coating film 3 due to rapid drying of the coating film 3.

The lower limit of the average thickness of the coating film 3 (the average thickness when the coating liquid for forming a conductive layer is applied once) is preferably 0.1 μm and more preferably 0.2 μm. The upper limit of the average thickness of the coating film 3 is preferably 0.5 μm and more preferably 0.4 μm. When the average thickness of the coating film 3 is less than the lower limit, a fine metal particle-sintered layer 4 obtained in a heating step described below may not have a sufficiently large thickness. In contrast, when the average thickness of the coating film 3 exceeds the upper limit, the density of the fine metal particles in the coating film 3 tends to become nonuniform, and consequently, it may become difficult to form a sufficiently dense fine metal particle-sintered layer. The term “average thickness” refers to an average of a thickness of a coating film portion where fine metal particles are present, the thickness being measured with an X-ray fluorescence thickness meter. The average can be determined by, for example, measuring the thickness at 10 positions at a rate of one position per area of 10 cm², and averaging the thicknesses at the 10 positions.

The upper limit of a surface roughness Sa of the coating film 3 is preferably 0.12 μm and more preferably 0.08 μm. When the surface roughness Sa of the coating film 3 exceeds the upper limit, it may become difficult to form the sufficiently dense fine metal particle-sintered layer 4. The lower limit of the surface roughness Sa of the coating film 3 is not particularly limited and may be, for example, 0.01 μm. The term “surface roughness Sa” refers to a value in accordance with ISO25178.

(Heating Step)

In the heating step, the coating film 3 is fired to form a fine metal particle-sintered layer 4, as illustrated in FIG. 2. In the heating step, by firing the coating film 3, the fine metal particles 2 are sintered together, and the resulting sintered body of the fine metal particles 2 is fixed to the one surface of the base film 1. The dispersant etc. and other organic substances contained in the coating film 3 are volatilized or decomposed by this firing.

Near the interface of the fine metal particle-sintered layer 4 with the base film 1, the fine metal particles are oxidized by heating to generate a metal oxide due to the metal of the fine metal particles or a group derived from the metal oxide while suppressing the generation of a metal hydroxide due to the metal or a group derived from the metal hydroxide. Specifically, for example, when copper is used as the fine metal particles, copper oxide and copper hydroxide are generated near the interface of the fine metal particle-sintered layer 4 with the base film 1, but copper oxide is generated in a larger amount than copper hydroxide. The copper oxide generated near the interface of the fine metal particle-sintered layer 4 is strongly bonded to, for example, a polyimide contained in the base film 1 as a main component, and thus the adhesive strength between the fine metal particle-sintered layer 4 and the base film 1 increases.

The heating step is performed in an atmosphere in which a certain amount of oxygen is contained. The lower limit of the oxygen concentration of the atmosphere during the heat treatment is preferably 1 ppm and more preferably 10 ppm. The upper limit of the oxygen concentration is preferably 10,000 ppm and more preferably 1,000 ppm. When the oxygen concentration is less than the lower limit, the amount of copper oxide generated near the interface of the fine metal particle-sintered layer 4 decreases, and sufficient adhesive strength between the fine metal particle-sintered layer 4 and the base film 1 may not be obtained. In contrast, when the oxygen concentration exceeds the upper limit, the fine metal particles are excessively oxidized, which may result in a decrease in the electrical conductivity of the fine metal particle-sintered layer 4.

The lower limit of the heating temperature is preferably 150° C. and more preferably 200° C. The upper limit of the heating temperature is preferably 500° C. and more preferably 400° C. When the heating temperature is lower than the lower limit, the amount of copper oxide generated near the interface of the fine metal particle-sintered layer 4 decreases, and sufficient adhesive strength between the fine metal particle-sintered layer 4 and the base film 1 may not be obtained. In contrast, when the heating temperature exceeds the upper limit, the base film 1 may be deformed in the case where the base film 1 is formed of an organic resin such as a polyimide.

(Metal Plating Layer Formation Step)

The metal plating layer formation step includes a first-metal plating layer formation step and a second-metal plating layer formation step.

(First-Metal Plating Layer Formation Step)

In the first-metal plating layer formation step, a first metal plating layer 5 is formed on an outer surface of the fine metal particle-sintered layer 4, as illustrated in FIG. 3. Specifically, in the first-metal plating layer formation step, gaps of the fine metal particle-sintered layer 4 are filled with a plated metal, and this plated metal is stacked on a surface of the fine metal particle-sintered layer 4. When the method for manufacturing a conductive layer includes the first-metal plating layer formation step, the adhesive strength between the conductive layer and the base film 1 can be increased.

The plating method for forming the first metal plating layer 5 is not particularly limited and may be electroless plating or electroplating. However, the plating method is preferably electroless plating, with which separation strength between the fine metal particle-sintered layer 4 and the base film 1 can be easily and reliably improved by more appropriately filling the gaps between the fine metal particles that form the fine metal particle-sintered layer 4.

The procedure when the electroless plating is employed is not particularly limited. The electroless plating can be performed by known means together with processes such as a cleaner step, a water-washing step, an acid treatment step, a water-washing step, a pre-dip step, an activator step, a water-washing step, a reduction step, and a water-washing step.

Also in the case where the electroplating is employed, the procedure is not particularly limited. For example, the procedure can be appropriately selected from known electrolytic plating baths and plating conditions.

After the gaps of the fine metal particle-sintered layer 4 are filled with the plated metal, heat treatment is preferably further performed. This heat treatment further increases the amount of copper oxide near the interface between the fine metal particle-sintered layer 4 and the base film 1. Thus, the adhesive strength between the fine metal particle-sintered layer 4 and the base film 1 can be further improved.

(Second-Metal Plating Layer Formation Step)

In the second-metal plating layer formation step, a second metal plating layer 6 is formed on an outer surface of the first metal plating layer 5, as illustrated in FIG. 4. When the method for manufacturing a conductive layer includes the second-metal plating layer formation step, the thickness of the conductive layer can be easily and reliably adjusted.

The plating method for forming the second metal plating layer 6 is not particularly limited and may be electroless plating or electroplating. However, the plating method is preferably electroplating, with which the thickness can be easily and accurately adjusted and the second metal plating layer 6 can be formed within a relatively short time.

The procedure when the electroless plating is employed is not particularly limited. The electroless plating can be performed by the same procedure as in the case of the formation of the first metal plating layer 5. Also in the case where the electroplating is employed, the procedure is not particularly limited. The electroplating can be performed by the same procedure as in the case of the formation of the first metal plating layer 5.

The conductive layer manufactured by the method for manufacturing a conductive layer is formed by patterning as a conductive pattern disposed on the one of surfaces of the base film 1. As a result, a printed circuit board including the base film 1 and the conductive pattern disposed on the one of surfaces of the base film 1 is manufactured.

### OTHER EMBODIMENTS

It is to be understood that the embodiments disclosed herein are only illustrative and are not restrictive in all respects. The scope of the present invention is not limited to the configurations of the embodiments and is defined by the claims described below. The scope of the present invention is intended to cover all the modifications within the meaning and scope of the claims and their equivalents.

For example, the coating liquid for forming a conductive layer is not necessarily used for forming a printed circuit board base material. The method for manufacturing a conductive layer is not necessarily carried out as a method for manufacturing a conductive layer of a printed circuit board base material.

Furthermore, when the method for manufacturing a conductive layer is carried out as a method for manufacturing a conductive layer of a printed circuit board base material, the method does not necessarily include the metal plating layer formation step. In the method for manufacturing a conductive layer, for example, the application step and the heating step may be performed a plurality of times to manufacture a conductive layer. According to the method for manufacturing a conductive layer, since the coating liquid for forming a conductive layer has a high content of the fine metal particles, a fine metal particle-sintered layer having a relatively large thickness can be formed by performing the application and the drying once. Therefore, in the method for manufacturing a conductive layer, a conductive layer can be manufactured by a small number of times of application. When the method for manufacturing a conductive layer includes the metal plating layer formation step, the method does not necessarily include both the first-metal plating layer formation step and the second-metal plating layer formation step. The method may include only the first-metal plating layer formation step. Furthermore, in the method for manufacturing a conductive layer, a conductive layer need not be formed only on one of surfaces of a base film. Alternatively, a conductive layer may be formed on each of two surfaces of a base film.

### EXAMPLES

The present invention will now be described in more detail by way of Examples. However, the present invention is not limited to the Examples.

### EXAMPLES

[No. 1]

In a beaker, 80 g (0.1 M) of a titanium trichloride solution serving as a reducing agent, 50 g of sodium carbonate serving as a pH adjuster, 90 g of sodium citrate serving as a complexing agent, and 1 g of polyethyleneimine serving as a dispersant are dissolved in 1 L of pure water, and the temperature of the resulting aqueous solution was maintained at 35° C. An aqueous solution of 10 g (0.04 M) of copper nitrate trihydrate, the temperature of which was maintained at the same temperature (35° C.), was added to the aqueous solution, and the aqueous solution was stirred to precipitate fine copper particles. Furthermore, the fine copper particles separated by centrifugation were repeatedly subjected to a washing step with 200 mL of pure water twice, and the fine copper particles were dried to prepare powdery fine copper particles. Subsequently, pure water was added to the powder fine copper particles to adjust the content. Thus, a coating liquid No. 1 for forming a conductive layer was prepared. Subsequently, 300 μL of the coating liquid No. 1 for forming a conductive layer was applied by bar coating onto a polyimide film (10 cm square) which had been subjected to a hydrophilic treatment.

[No. 2 to No. 5]

Coating liquids No. 2 to No. 5 for forming conductive layers were prepared as in No. 1 except that the amount of water used in each washing step was changed as shown in Table 1. The coating liquids No. 2 to No. 5 for forming conductive layers were each applied as in No. 1 by bar coating onto a polyimide film (10 cm square) which had been subjected to a hydrophilic treatment.

[No. 6 to No. 9]

Coating liquids No. 6 to No. 9 for forming conductive layers were prepared as in No. 1 except that the contents of the fine copper particles in the coating liquids for forming conductive layers were changed as shown in Table 1. The coating liquids No. 6 to No. 9 for forming conductive layers were each applied as in No. 1 by bar coating onto a polyimide film (10 cm square) which had been subjected to a hydrophilic treatment.

[No. 10]

A coating liquid No. 10 for forming a conductive layer was prepared as in No. 1 except that 1 g of a polyethyleneimine-ethylene oxide adduct was used as the dispersant. The coating liquid No. 10 for forming a conductive layer was applied as in No. 1 by bar coating onto a polyimide film (10 cm square) which had been subjected to a hydrophilic treatment.

[No. 11]

A coating liquid No. 11 for forming a conductive layer was prepared as in No. 1 except that 1 g of a polyethylenehnine-ethylene oxide adduct was used as the dispersant, and the amount of water used in each washing step was changed as shown in Table 1. The coating liquid No. 11 for forming a conductive layer was applied as in No. 1 by bar coating onto a polyimide film (10 cm square) which had been subjected to a hydrophilic treatment.

### COMPARATIVE EXAMPLES

[No. 12 and No. 13]

Coating liquids No. 12 and No. 13 for forming conductive layers were prepared as in No. 1 except that the amount of water used in each washing step was changed as shown in Table 1. The coating liquids No. 12 and No. 13 for forming conductive layers were each applied as in No. 1 by bar coating onto a polyimide film (10 cm square) which had been subjected to a hydrophilic treatment.

[No. 14 and No. 15]

Coating liquids No. 14 and No. 15 for forming conductive layers were prepared as in No. 1 except that the contents of the fine copper particles in the coating liquids for forming conductive layers were changed as shown in Table 1. The coating liquids No. 14 and No. 15 for forming conductive layers were each applied as in No. 1 by bar coating onto a polyimide film (10 cm square) which had been subjected to a hydrophilic treatment.

[No. 16]

A coating liquid No. 16 for forming a conductive layer was prepared as in No. 1 except that 1 g of a polyethyleneimine-ethylene oxide adduct was used as the dispersant, the amount of water used in each washing step was changed to be the same as that in No. 11, and 0.2 g of hydrochloric acid was added after pure water was added to the powdery fine copper particles. The coating liquid No. 16 for forming a conductive layer was applied as in No. 1 by bar coating onto a polyimide film (10 cm square) which had been subjected to a hydrophilic treatment.

<Electrical Conductivity>

An electrical conductivity [μS/cm] of each of the coating liquids for forming conductive layers was measured in accordance with JIS-K0130: 2008 by using a compact electrical conductivity meter “LAQUAtwin B-771” available from HORIBA, Ltd. The results of this measurement are shown in Table 1.

<Viscosity>

A viscosity [mPa·s] of each of the coating liquids for forming conductive layers was measured in accordance with JIS-Z8803: 2011 under the conditions of 25° C. at 20 rpm by using a cone-plate viscometer “TV22L” available from TOKI SANGYO Co., Ltd. The results of this measurement are shown in Table 1.

<Coating Film Thickness>

A coating film thickness was measured by using an X-ray fluorescence thickness meter “FT9500” available from Hitachi High-Tech Science Corporation. The coating film thickness was determined by measuring a thickness of a portion where fine copper particles were present at 10 positions at a rate of one position per area of 10 cm², and averaging the thicknesses at the 10 positions. The results of this measurement are shown in Table 1.

<Surface Roughness>

A surface of a coating film formed by applying each of the coating liquids for forming conductive layers was observed with a laser microscope “VK-X150” available from KEYENCE Corporation at an objective lens magnification of 100 and at a digital zoom of 1 time. An area in the range of 30 μm×30 μm was analyzed at a height cut level of 90 to measure a surface roughness Sa [μm] in accordance with ISO25178. The results of this measurement are shown in Table 1.

<Thin Spot>

A coating film formed by applying each of the coating liquids for forming conductive layers was visually observed to examine the presence or absence of void. When void was present, the coating film was evaluated that “a thin spot was present”. When void was absent, the coating film was evaluated that “a thin spot was absent”. The results of this evaluation are shown in Table 1.

<Average Particle Size D_{50 SEM}>

When surfaces of fine metal particles (fine copper particles) were observed with a scanning electron microscope (SEM) at a magnification of 100 k to 300 k to measure the sizes of 100 fine metal particles that were arbitrarily selected, and the volume was accumulated in the ascending order of the particle size, a particle size [nm] at which the cumulative volume was 50% was measured. The results of this measurement are shown in Table 1.

<Average Particle Size D₅₀>

An average particle size D₅₀ [nm] of fine metal particles (fine copper particles), the average particle size D₅₀ being calculated from a cumulative volume distribution, was measured by using a particle size distribution analyzer “Nanotrac Wave-EX150” available from MicrotracBEL Corporation. The results of this measurement are shown in Table 1.

TABLE 1

| | Coating liquid for forming conductive layer | | | | | | | | | | |
|---|---|---|---|---|---|---|---|---|---|---|---|
| | | | | | Fine metal particle | | | | | | |
| | | | Fine metal | | Average | Average | | Amount of | Coating film | | |
| | | Electrical | particle | | particle | particle | | washing | | Surface | |
| | | conductivity | content | Viscosity | size D_{50SEM} | size D₅₀ | D_{50SEM}/ | water | Thickness | roughness | Thin |
| | pH | [μS/cm] | [mass %] | [mPa · s] | [nm] | [nm] | D₅₀ | [mL] | [μm] | [μm] | spot |
| No. 1 | 7.0 | 270 | 30 | 1.2 | 93 | 89 | 1.0 | 200 | 0.19 | 0.058 | Absent |
| No. 2 | 7.6 | 420 | 30 | 1.2 | 98 | 79 | 1.2 | 150 | 0.21 | 0.098 | Absent |
| No. 3 | 8.0 | 780 | 30 | 1.4 | 116 | 83 | 1.4 | 100 | 0.23 | 0.119 | Absent |
| No. 4 | 6.3 | 104 | 30 | 1.2 | 104 | 72 | 1.4 | 300 | 0.26 | 0.111 | Absent |
| No. 5 | 6.8 | 180 | 30 | 1.1 | 104 | 87 | 1.2 | 250 | 0.24 | 0.092 | Absent |
| No. 6 | 7.0 | 200 | 20 | 1.0 | 85 | 64 | 1.3 | 200 | 0.11 | 0.079 | Absent |
| No. 7 | 7.4 | 310 | 45 | 11 | 156 | 130 | 1.2 | 200 | 0.25 | 0.085 | Absent |
| No. 8 | 7.3 | 350 | 60 | 32 | 136 | 104 | 1.3 | 200 | 0.32 | 0.104 | Absent |
| No. 9 | 7.1 | 480 | 80 | 89 | 134 | 97 | 1.4 | 200 | 0.42 | 0.114 | Absent |
| No. 10 | 5.6 | 510 | 30 | 1.1 | 30 | 28 | 1.1 | 200 | 0.18 | 0.045 | Absent |
| No. 11 | 4.4 | 260 | 30 | 1.3 | 38 | 35 | 1.1 | 300 | 0.19 | 0.063 | Absent |
| No. 12 | 8.2 | 880 | 30 | 1.7 | 297 | 90 | 3.3 | 60 | 0.28 | 0.172 | Absent |
| No. 13 | 5.8 | 87 | 30 | 1.5 | 232 | 76 | 3.1 | 400 | 0.25 | 0.189 | Absent |
| No. 14 | 6.8 | 160 | 15 | 0.9 | 85 | 78 | 1.1 | 200 | 0.07 | 0.064 | Absent |
| No. 15 | 7.3 | 790 | 85 | 123 | 210 | 98 | 2.1 | 200 | 0.62 | 0.143 | Present |
| No. 16 | 3.8 | 640 | 30 | 1.5 | 110 | 28 | 3.9 | 300 | 0.21 | 0.183 | Absent |

[Evaluation Results]

Table 1 shows the following. Since the coating liquids No. 1 to No. 11 for forming conductive layers are adjusted to have a pH of 4 or more and 8 or less, an electrical conductivity of 100 μS/cm or more and 800 μS/cm or less, and a content of the fine metal particles (fine copper particles) of 20% by mass or more and 80% by mass or less, the coating liquids can provide coating films having a relatively large thickness of 0.1 μm or more and a relatively small surface roughness Sa of 0.12 μm or less. In particular, since the coating liquids No. 1, No. 10, and No. 11 for forming conductive layers each have a small ratio of average particle size D_{50 SEM}/average particle size D₅₀, specifically, 1.1 or less, the fine metal particles (fine copper particles) have a uniform and substantially spherical shape. As a result, these fine metal particles are easily uniformly dispersed in the coating films at a high density, and thus the surface roughness Sa of each of the coating films can be decreased to 0.063 μm or less. On the other hand, regarding each of the coating liquids No. 12 to No. 16 for forming conductive layers, the pH, the electrical conductivity, and the content of the fine metal particles (fine copper particles) are not adjusted to the above ranges. Accordingly, it is difficult to form a coating film having a relatively large thickness and a relatively small surface roughness Sa. In particular, regarding each of the coating liquids No. 12, No. 13, No. 15, and No. 16 for forming conductive layers, the average particle size D_{50 SEM} is relatively large, and the ratio of average particle size D_{50 SEM}/average particle size D₅₀ is large, that is, 2.1 or more. Therefore, the surface roughness Sa of the coating film cannot be sufficiently reduced, and it is difficult to form a sufficiently dense conductive layer. Furthermore, since the coating liquid No. 15 for forming a conductive layer has a high viscosity of 123 mPa·s, which exceeds 100 mPa·s, the coating film is unlikely to spread uniformly on the polyimide film, resulting in the generation of thin spots of the coating film.

### REFERENCE SIGNS LIST

1 base film
2 fine metal particle
3 coating film
4 fine metal particle-sintered layer
5 first metal plating layer
6 second metal plating layer

1. A coating liquid for forming a conductive layer, the coating liquid comprising fine metal particles, a dispersion medium, and a dispersant,
wherein the coating liquid has a pH of 4 or more and 8 or less, an electrical conductivity of 100 μS/cm or more and 800 μS/cm or less, and a content of the fine metal particles of 20% by mass or more and 80% by mass or less.

2. The coating liquid for forming a conductive layer according to claim 1, wherein the dispersant comprises a polymer compound.

3. The coating liquid for forming a conductive layer according to claim 2, wherein the polymer compound has an imino group.

4. The coating liquid for forming a conductive layer according to claim 3, wherein the polymer compound comprises polyethyleneimine or a polyethyleneimine-ethylene oxide adduct.

5. The coating liquid for forming a conductive layer according to claim 1, wherein the fine metal particles have an average particle size D₅₀ of 1 nm or more and 500 nm or less, the average particle size D₅₀ being calculated from a cumulative volume distribution measured by a laser diffraction method.

6. The coating liquid for forming a conductive layer according to claim 1, wherein the coating liquid has a viscosity of 100 mPa·s or less at 25° C.

7. The coating liquid for forming a conductive layer according to claim 1, wherein the fine metal particles contain copper or a copper alloy as a main component.

8. A method for manufacturing a conducting layer using a coating liquid for forming a conductive layer, the coating liquid containing fine metal particles, a dispersion medium, and a dispersant, the method comprising:
an application step of applying the coating liquid for forming a conductive layer; and
a heating step of heating the coating liquid for forming a conductive layer after application,
wherein, at the time of the application, the coating liquid for forming a conductive layer has a pH of 4 or more and 8 or less, an electrical conductivity of 100 μS/cm or more and 800 μS/cm or less, and a content of the fine metal particles of 20% by mass or more and 80% by mass or less.
